(19) United States
(12) Patent Application Publication
(10) Pub. No.: US 2024/0258365 A1
(43) Pub. Date: Aug. 1, 2024

(54) CAPACITOR AND DEVICE INCLUDING THE SAME

(71) Applicant: Samsung Electronics Co., Ltd., Suwon-si (KR)

(72) Inventors: Jinhong KIM, Suwon-si (KR); Changsoo LEE, Suwon-si (KR); Cheheung KIM, Hwaseong-si (KR); Jooho LEE, Suwon-si (KR)

(73) Assignee: Samsung Electronics Co., Ltd., Suwon-si (KR)

(21) Appl. No.: 18/541,848

(22) Filed: Dec. 15, 2023

(30) Foreign Application Priority Data
Jan. 27, 2023 (KR) 10-2023-0011218

(51) Int. Cl. H01G 4/10; H01G 4/008; H10B 12/00

(52) U.S. Cl. CPC H01L 28/75; H01G 4/008; H01G 4/10; H10B 12/315

(57) ABSTRACT

Provided is a capacitor including a first thin film electrode layer, a second thin film electrode layer, a dielectric layer disposed between the first thin film electrode layer and the second thin film electrode layer, and an interlayer disposed between the second thin film electrode layer and the dielectric layer. Due to the interlayer, the decrease in permittivity of the dielectric layer is small while leakage current may be effectively reduced.

### CROSS-REFERENCE TO RELATED APPLICATION

This application is based on and claims priority under 35 U.S.C. § 119 to Korean Patent Application No. 10-2023-0011218, filed on Jan. 27, 2023, in the Korean Intellectual Property Office, the disclosures of which are incorporated by reference herein in their entirety.

### BACKGROUND

### 1. Field

The disclosure relates to a capacitor and a device including the same.

### 2. Description of the Related Art

Electronic devices, such as memories, capacitors, and transistors, are used in various household and industrial devices. With the high performance of household and industrial devices, such electronic devices are becoming highly integrated and miniaturized. In response to the high integration and miniaturization of the electronic devices, the sizes of such electronic devices have also decreased. For example, as the size of capacitors has decreased, the capacity of capacitors has decreased and leakage current has increased. Accordingly, various methods are proposed to solve this issue.

For example, the capacitance of a capacitor is maintained by changing the structure of the capacitor, by, for example, increasing the electrode area of the capacitor or decreasing the thickness of a dielectric. However, when a thickness of the dielectric is decreased too low, the capacitance of the capacitor may decrease due to an increase in leakage current. Therefore, dielectrics with improved effective oxide film thicknesses (T_{oxeq}) are being researched to satisfy the demands for high integration.

### SUMMARY

Provided are a capacity having a novel structure and a device including the same.

Additional aspects will be set forth in part in the description which follows and, in part, will be apparent from the description, or may be learned by practice of the presented embodiments of the disclosure.

According to an aspect of the disclosure, a capacitor includes a first thin film electrode layer, a second thin film electrode layer, and a dielectric layer disposed between the first thin film electrode layer and the second thin film electrode layer, and an interlayer between the second thin film electrode layer and the dielectric layer, the interlayer including a first metal oxide and a second metal oxide having a rutile phase, wherein the dielectric layer includes a third metal oxide having a rutile-phase, the first metal oxide includes at least one of Al₂O₃ or MgO, the second metal oxide includes at least one of SnO₂, GeO₂, or MnO₂, the third metal oxide may include at least one TiO₂, Ti₁₋ₓGaₓO₂ (0.01≤x≤0.1), Ti₁₋ₓAlₓO₂ (0.01≤x≤0.1), Ti₁₋ₓLaₓO₂ (0.01≤x≤0.1), Ti₁₋ₓBₓO₂ (0.01≤x≤0.1), Ti₁₋ₓInₓO₂ (0.01≤x≤0.1), Ti₁₋ₓScₓO₂ (0.01≤x≤0.1), Ti₁₋ₓYₓO₂ (0.01≤x≤0.1), and the first metal oxide, the second metal oxide, and the third metal oxide have different compositions.

According to another aspect of the disclosure, a capacitor includes a first thin film electrode layer, a second thin film electrode layer, and a dielectric layer between the first thin film electrode layer and the second thin film electrode layer, and an interlayer between the second thin film electrode layer and the dielectric layer, the interlayer including a first metal oxide and a second metal oxide having a rutile-phase crystal structure, wherein the dielectric layer includes a third metal oxide having a rutile-phase, the first metal oxide, the second metal oxide, and the third metal oxide have different compositions, the band gap energy of the first metal oxide is 5.0 eV or more, the chemical potential of the second metal oxide is greater than that of the third metal oxide, and the third metal oxide may include at least one of TiO₂, Ti₁₋ₓGaₓO₂ (0.01≤x≤0.1), Ti₁₋ₓAlₓO₂ (0.01≤x≤0.1), Ti₁₋ₓLaₓO₂ (0.01≤x≤0.1), Ti₁₋ₓBₓO₂ (0.01≤x≤0.1), Ti₁₋ₓInₓO₂ (0.01≤x≤0.1), Ti₁₋ₓScₓO₂ (0.01≤x≤0.1), Ti₁₋ₓYₓO₂ (0.01≤x≤0.1).

According to another aspect of the disclosure, a device that includes the capacitor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a schematic structure of a capacitor according to at least one embodiment;

FIG. 2 is a cross-sectional view showing a schematic structure of a capacitor according to at least one embodiment;

FIG. 3 shows a high-resolution transmission electron microscopy (HR-TEM) image of a cross-section of a first thin film electrode layer/third interlayer/dielectric layer/second interlayer/first interlayer stack manufactured in Example 1;

FIG. 4 is an enlarged image of a part of the HR-TEM image of FIG. 3;

FIGS. 5A to 5F show energy dispersive spectroscopy (EDS) elemental mapping images of a cross-section of the first thin film electrode layer/third interlayer/dielectric layer/second interlayer/first interlayer stack manufactured in Example 1;

FIG. 6 is a graph of leakage current according to effective oxide film thickness (T_{oxeq}) with respect to capacitors manufactured in Examples 1 and 2 and Comparative Examples 1 to 5;

FIG. 7 is a graph of leakage current according to effective oxide film thickness (T_{oxeq}) with respect to capacitors manufactured in Examples 1, 3, 4, and 5 and Comparative Example 1, 2, and 6;

FIG. 8 is a graph showing electron affinity of metal oxides and work function of MoO₂;

FIG. 9 is a circuit diagram illustrating a schematic circuit configuration and operation of an electronic device using a capacitor according to some embodiments;

FIG. 10 is a schematic diagram illustrating an electronic device according to at least one embodiment;

FIG. 11 is a schematic diagram illustrating an electronic device according to at least one embodiment;

FIG. 12 is a plan view illustrating an electronic device according to at least one embodiment;

FIG. 13 is a cross-sectional view taken along line A-A′ of FIG. 11;

FIG. 14 is a cross-sectional view illustrating an electronic device according to at least one embodiment; and

FIGS. 15 and 16 are conceptual diagrams schematically illustrating device architectures that may be applied to devices according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one selected from,” when preceding a list of elements, modify the entire list of elements and do not modify the individual elements of the list.

The present inventive concepts described hereinafter may be modified in various ways, and may have many examples, and thus, particular examples are illustrated in the drawings, and are described in detail. The present inventive concepts, however, should not be construed as limited to the particular embodiments set forth herein, and rather, should be understood as covering all modifications, equivalents, or alternatives falling within the scope of the present inventive concept.

The terms used herein are for the purpose of describing particular embodiments only, and is not intended to be limiting the present inventive concept. An expression used in the singular encompasses the expression of the plural, unless it has a clearly different meaning in the context. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The sign “/” used herein may be interpreted as “and”, or as “or” depending on the context. Additionally, when the terms “about” or “substantially” are used in this specification in connection with a numerical value and/or geometric terms, it is intended that the associated numerical value includes a manufacturing tolerance (e.g., ±10%) around the stated value and/or term. Further, regardless of whether numerical values and/or geometric terms are modified as “about” or “substantially,” it will be understood that these values should be construed as including a manufacturing or operational tolerance (e.g., ±10%) around the stated numerical values and/or geometry. When referring to “within” and/or “C to D”, this means C inclusive to D inclusive unless otherwise specified.

In addition, functional terms such as those including “. . . unit” described in the specification refer to a unit that is configured to process at least one function or operation, which may be implemented through processing circuitry such as hardware or software or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Connections of lines between components shown in the drawings, or connecting members are examples of functional connections and/or physical or circuit connections, which can be replaced in actual devices or additional various functional connections, physical connections, or as circuit connections.

In the drawings, thicknesses may be magnified or exaggerated to clearly illustrate various layers and regions. Like reference numbers may refer to like elements throughout the drawings and the following description. It will be understood that when a layer, a film, a region, a sheet, etc. is referred to as being “on” another layer, another film, another region, another sheet, etc., it can be directly on the other element or intervening elements may be present therebetween. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

Although the terms “first,” “second,” etc. may be used herein to describe various elements, these elements should not be limited by these terms. These terms are only used to distinguish one element from another element. Components having substantially the same functional features in the present specification and drawings are denoted by the same reference numerals, and redundant description is omitted.

The term “chemical potential of a metal oxide” used herein is a measure of the chemical stability of a metal oxide. In the case of metal oxides with high chemical potential, the probability that the metal oxides lose oxygen and are thereby reduced to metals, is high. In the case of metal oxides with low chemical potential, the probability that metal oxides lose oxygen and are reduced to metals, is low.

Hereinafter, a capacitor according to embodiments and a device including the same will be described in more detail.

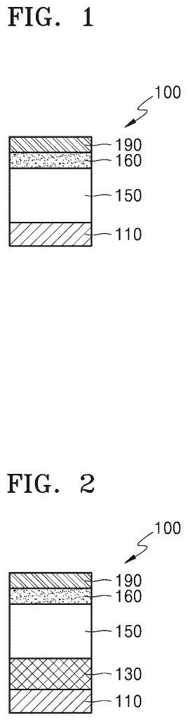

FIGS. 1 and 2 are each a cross-sectional view showing a schematic structure of a capacitor 100 according to at least one embodiment.

The capacitor 100 according to at least one embodiment includes a first thin film electrode layer 110, second thin film electrode layer 190, and a dielectric layer 150 disposed between the first thin film electrode layer 110 and the second thin film electrode layer 190, and an interlayer 160 disposed between the second thin film electrode layer and the dielectric layer, wherein the interlayer includes a first metal oxide and a second metal oxide having a rutile-phase crystal structure, the dielectric layer includes a third metal oxide having a rutile-phase crystal structure, the first metal oxide, the second metal oxide, and the third metal oxide have different compositions, the first metal oxide includes Al₂O₃, MgO, and/or a combination thereof, the second metal oxide includes SnO₂, GeO₂, MnO₂, and/or a combination thereof, the third metal oxide may include TiO₂, Ti₁₋ₓGaₓO₂ (0.01≤x≤0.1), Ti₁₋ₓAlₓO₂ (0.01≤x≤0.1), Ti₁₋ₓLaₓO₂ (0.01≤x≤0.1), Ti₁₋ₓBₓO₂ (0.01≤x≤0.1), Ti₁₋ₓInₓO₂ (0.01≤x≤0.1), Ti₁₋ₓScₓO₂ (0.01≤x≤0.1), Ti₁₋ₓYₓO₂ (0.01≤x≤0.1), and/or a combination thereof.

Referring to FIGS. 1 and 2, a dielectric layer 150 is disposed between a first thin film electrode layer 110 and a second thin film electrode layer 190, and an interlayer 160 is disposed between the second thin film electrode layer 190 and the dielectric layer 150.

According to at least one embodiment, the interlayer 160 disposed between the second thin film electrode layer 190 and the dielectric layer 150 includes a third metal oxide having a rutile-phase crystal structure, and includes a first metal oxide including Al₂O₃, MgO, and/or a combination thereof, and the leakage current between the electrode layer and the dielectric layer is reduced due to the high bandgap energy of the first metal oxide.

In addition, since the interlayer 160 includes a second metal oxide including SnO₂, GeO₂, MnO₂, and/or a combination thereof, each having a rutile-phase crystal structure, deterioration at the interface between the dielectric layer and the interlayer is suppressed during the capacitor manufacturing process, and as the rutile-phase crystal structure of the third metal oxide in the dielectric layer is maintained, high permittivity characteristics are maintained and the leakage current between the electrode layer and the dielectric layer may be further reduced.

According to at least one embodiment, the ratio of the content of the second metal oxide to the content of the first metal oxide may be at least about 1 atomic percentage (at %) and not more than about 90 at %. For example, the ratio of the content of the second metal oxide to the content of the first metal oxide may be at least 1 at % and not more than 90 at %, at least 1 at % and not more than 80 at %, at least 10 at % and not more than 80 at %, and/or the like.

As the ratio of the content of the second metal oxide to the content of the first metal oxide is within these ranges, deterioration of the dielectric layer is prevented without substantially affecting the permittivity of the capacitor, resulting in high permittivity and low leakage current characteristics.

According to at least one embodiment, the interlayer 160 includes a second interlayer disposed between a first interlayer and the dielectric layer, the first interlayer includes the first metal oxide, and the second interlayer includes the second metal oxide.

According to at least one embodiment, the thickness of the first interlayer may be at least about 0.5 angstrom (Å) and less than about 10 Å. For example, the thickness of the first interlayer may be at least about 0.5 Å and less than about 10 Å, at least about 1 Å and less than about 10 Å, or at least about 1 Å and less than about 5 Å, but the examples are not limited thereto.

According to at least one embodiment, the thickness of the second interlayer may be less than about 1 Å. For example, the second interlayer may have a thickness of less than about 1 Å, less than about 0.95 Å, less than about 0.9 Å, and/or the like. In cases wherein the thickness range of the second interlayer is satisfied, deterioration of the dielectric layer is prevented without substantially affecting the permittivity of the capacitor, resulting in high permittivity characteristics and low leakage current characteristics together.

According to at least one embodiment, a third interlayer 130 disposed between the first thin film electrode layer 110 and the dielectric layer 150 is further included, and the third interlayer 130 includes a fourth metal oxide having a rutile-phase crystal structure. The fourth metal oxide may for example, include SnO₂, GeO₂, MnO₂, and/or a combination thereof (see FIG. 2).

Since the third interlayer 130 including the fourth metal oxide having the rutile-phase crystal structure is further included, due to the retaining the rutile-phase crystal structure of the third metal oxide in the dielectric layer, high permittivity is maintained, and when a material with a higher electronegativity than the dielectric layer is used, the leakage current between the electrode layer and the dielectric layer may be further reduced.

According to at least one embodiment, the first thin film electrode layer may include TiN.

According to at least one embodiment, the first thin film electrode layer 110 may include a second lower electrode layer (not illustrated) spaced apart from the dielectric layer and a first lower electrode layer (not illustrated) disposed between the second lower electrode layer and the dielectric layer. In these embodiments, the first lower electrode layer includes a fifth metal oxide having a rutile-phase crystal structure, and the fifth metal oxide may include MoO₂, VO₂, Mo₁₋ₓNbₓO₂ (0.01≤x≤0.1), Mo₁₋ₓTaₓO₂ (0.01≤x≤0.1), Mo₁₋ₓSbₓO₂ (0.01≤x≤0.1), Mo₁₋ₓMnₓO₂ (0.01≤x≤0.1), Mo₁₋ₓFeₓO₂ (0.01≤x≤0.1), V₁₋ₓNbₓO₂ (0.01≤x≤0.1), V₁₋ₓTaₓO₂ (0.01≤x≤0.1), V₁₋ₓSbₓO₂ (0.01≤x≤0.1), V₁₋ₓMnₓO₂ (0.01≤x≤0.1), V₁₋ₓFeₓO₂ (0.01≤x≤0.1), and/or a combination thereof.

Since the first thin film electrode layer 110 further includes the first lower electrode layer including the fifth metal oxide, a high conductive band offset may be obtained while the rutile structure in the capacitor is maintained, resulting in the decrease in the leakage current in the capacitor.

According to at least one embodiment, the fifth metal oxide is be a conductive metal oxide.

According to at least one embodiment, the chemical potential of the second metal oxide is greater than that of the third metal oxide.

Since the second interlayer includes the second metal oxide, the dielectric layer includes the third metal oxide, and the chemical potential of the second metal oxide is higher than that of the third metal oxide, oxygen ions may move more easily from the second interlayer to the first interlayer than from the dielectric layer to first interlayer. When the first interlayer is directly deposited on the dielectric layer, the third metal oxide may be easily reduced due to the movement of oxygen ions from the third metal oxide of the dielectric layer to the first metal oxide of the first interlayer. On the other hand, since the second interlayer including the second metal oxide is further disposed on the dielectric layer, although the second metal oxide can be reduced by the movement of oxygen ions from the second metal oxide of the second interlayer to the first interlayer, the movement of oxygen ions from the third metal oxide to the second interlayer is suppressed due to the difference in chemical potential, and thus, the reduction of the third metal oxide may be suppressed. As a result, since the reduction in the work function of the dielectric layer including the third metal oxide due to the reduction of the third metal oxide is prevented, an increase in the leakage current between the dielectric layer and the second thin film electrode layer may be suppressed.

According to at least one embodiment, the dielectric layer may have a thickness of at least about 2 nm and not more than about 10 nm. For example, the thickness of the dielectric layer may be at least 2 nm and not more than 10 nm, at least 2 nm and not more than 9 nm, or at least 3 nm and not more than 10 nm, but the examples are not limited thereto.

According to at least one embodiment, the thickness of the first thin film electrode layer and the thickness of the second thin film electrode layer may each independently be at least about 10 nm and not more than about 20 nm. For example, the thickness of the dielectric layer may be at least 10 nm and not more than 20 nm, at least 11 nm and not more than 20 nm, or at least 10 nm and not more than 19 nm, but is not limited thereto.

According to at least one embodiment, provided is the capacitor 100 including the first thin film electrode layer 110, the second thin film electrode layer 190, and the dielectric layer 150 disposed between the first thin film electrode layer 110 and the second thin film electrode layer 190, and the interlayer 160 disposed between the second thin film electrode layer 190 and the dielectric layer 150, the interlayer 160 includes a first metal oxide and a second metal oxide having a rutile-phase crystal structure, the dielectric layer includes a third metal oxide having a rutile-phase crystal structure, the first metal oxide, the second metal oxide, and the third metal oxide have different compositions, the band gap energy of the first metal oxide is 5.0 eV or more, the chemical potential of the second metal oxide is greater than that of the third metal oxide, and the third metal oxide may include TiO₂, Ti₁₋ₓGaₓO₂ (0.01≤x≤0.1), Ti₁₋ₓAlₓO₂ (0.01≤x≤0.1), Ti₁₋ₓLaₓO₂ (0.01≤x≤0.1), Ti₁₋ₓBₓO₂ (0.01≤x≤0.1), Ti₁₋ₓInₓO₂ (0.01≤x≤0.1), Ti₁₋ₓScₓO₂ (0.01≤x≤0.1), Ti₁₋ₓYₓO₂ (0.01≤x≤0.1), or a combination thereof.

For example, the capacitor includes the interlayer 160 disposed between the second thin film electrode layer 190 and the dielectric layer 150 including the third metal oxide having a rutile-phase crystal structure, and since the interlayer 160 includes the first metal oxide having a bandgap energy of 5.0 eV or more, due to the high bandgap energy of the first metal oxide, the leakage current between the electrode layer and the dielectric layer may be reduced.

In addition, since the interlayer 160 has the second metal oxide that has a rutile-phase crystal structure and has a higher chemical potential than the third metal oxide, deterioration at the interface between the dielectric layer 150 and the interlayer 160 during the capacitor manufacturing process is suppressed, and due to the retaining the rutile-phase crystal structure of the third metal oxide in the dielectric layer 150, high permittivity characteristics are maintained, and leakage current between the electrode layer and the dielectric layer may be further reduced.

According to at least one embodiment, the ratio of the content of the second metal oxide to the content of the first metal oxide may be at least about 1 at % and not more than about 90 at %. For example, the content ratio may be at least 1 at % and not more than 90 at %, at least 1 at % and not more than 80 at %, at least 10 at % and not more than 80 at %, and/or the like.

As the ratio of the content of the second metal oxide to the content of the first metal oxide is within these ranges, deterioration of the dielectric layer is prevented without substantially affecting the dielectric constant of the capacitor, resulting in high dielectric constant and low leakage current characteristics.

According to at least one embodiment, the interlayer 160 includes a second interlayer disposed between a first interlayer and the dielectric layer, the first interlayer includes the first metal oxide, and the second interlayer includes the second metal oxide.

According to at least one embodiment, the thickness of the first interlayer may be at least about 0.5 Å and less than about 10 Å. For example, the thickness of the first interlayer may be at least about 0.5 Å and less than about 10 Å, at least about 1 Å and less than about 10 Å, and/or at least about 1 Å and less than about 5 Å, but the examples are not limited thereto.

According to at least one embodiment, the thickness of the second interlayer may be less than about 1 Å. For example, the second interlayer may have a thickness of less than about 1 Å, less than about 0.95 Å, or less than about 0.9 Å, but is not limited thereto.

As the thickness range of the second interlayer is satisfied, deterioration of the dielectric layer is prevented without substantially affecting the permittivity of the capacitor, resulting in high permittivity characteristics and low leakage current characteristics together.

According to at least one embodiment, the third interlayer 130 disposed between the first thin film electrode layer 110 and the dielectric layer 150 may be further included, the first thin film electrode layer 110 may include a second lower electrode layer disposed apart from the dielectric layer and a first lower electrode layer disposed between the second lower electrode layer and the dielectric layer, the third interlayer includes a fourth metal oxide having a rutile-phase crystal structure, the first lower electrode layer includes a fifth metal oxide having a rutile-phase crystal structure, and the third metal oxide, the fourth metal oxide, and the fifth metal oxide may have different compositions (see FIG. 2).

According to at least one embodiment, the first metal oxide may include Al₂O₃, MgO, or a combination thereof.

Al₂O₃ has a band gap energy of about 7.0 eV to about 8.7 eV, and MgO has a band gap energy of about 7.8 eV, thereby satisfying a band gap energy range of 5.0 eV or more.

According to at least one embodiment, the second metal oxide and the fourth metal oxide may each independently include SnO₂, GeO₂, MnO₂, or a combination thereof.

According to at least one embodiment, the second metal oxide and the fourth metal oxide may be identical to or different from each other.

According to at least one embodiment, the fifth metal oxide may be a conductive metal oxide.

According to at least one embodiment, the fifth metal oxide may include MoO₂, VO₂, Mo₁₋ₓNbₓO₂ (0.01≤x≤0.1), Mo₁₋ₓTaₓO₂ (0.01≤x≤0.1), Mo₁₋ₓSbₓO₂ (0.01≤x≤0.1), Mo₁₋ₓMnₓO₂ (0.01≤x≤0.1), Mo₁₋ₓFeₓO₂ (0.01≤x≤0.1), V₁₋ₓNbₓO₂ (0.01≤x≤0.1), V₁₋ₓTaₓO₂ (0.01≤x≤0.1), V₁₋ₓSbₓO₂ (0.01≤x≤0.1), V₁₋ₓMnₓO₂ (0.01≤x≤0.1), V₁₋ₓFeₓO₂ (0.01≤x≤0.1), or a combination thereof.

According to at least one embodiment, the first thin film electrode layer may include TiN.

According to at least one embodiment, the second thin film electrode layer 190 includes a conductive material, which is not particularly limited. Like the first thin film electrode layer 110, the second thin film electrode layer 190 may have a rutile phase, but may include various conductive materials having a different phase. The second thin film electrode layer 190 may include metal, metal nitride, metal oxide, or a combination thereof. For example, the second electrode 140 may include TiN, MoN, CoN, TaN, W, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), and/or a combination of these.

According to at least one embodiment, an electronic device is provided including a transistor and any one of the capacitors, described above, electrically connected to the transistor.

The transistor may include: a semiconductor substrate including a source region, a drain region, and a channel region positioned between the source region and the drain region; and a gate stack disposed on the semiconductor substrate to face the channel region and including a gate insulating layer and a gate electrode.

The transistor may include: a semiconductor substrate including a source region, a drain region, and a channel region positioned between the source region and the drain region; and a gate stack disposed in a gate line trench extending to a certain depth from a surface of the semiconductor substrate, to face the channel region, and including a gate insulating layer and a gate electrode.

The electronic device may include: a memory unit including the capacitor and the transistor; and a control unit electrically connected to the memory unit and controlling the memory unit.

The capacitor may be included in various electronic devices. The capacitor may be used as a dynamic random access memory (DRAM) device together with a transistor. In addition, the capacitor may form a part of an electronic circuit constituting an electronic device together with other circuit elements.

FIG. 9 is a circuit diagram illustrating a schematic circuit configuration and operation of an electronic device 1000 using a capacitor according to some embodiments.

The circuit diagram of the electronic device 1000 is of one cell of a dynamic random access memory (DRAM) device, and may include one transistor TR, one capacitor CA, a word line WL, and a bit line BL. The capacitor CA may be the capacitor 100 described in FIGS. 1 to 7.

A gate voltage (high) that makes the transistor TR be in an ON state, may be applied to a gate electrode through the word line WL, and then, VDD (high), which is the data voltage value to be input to bit line BL, or 0 (low) is applied. When high voltage is applied to a word line and a bit line, the capacitor CA is charged and data (e.g., “1”) is written. When high voltage is applied to a word line and low voltage is applied to bit line, the capacitor CA is discharged and data (e.g., “0”) is written.

When reading data, a high voltage is applied to the word line WL to turn on the DRAM transistor TR, and then a voltage of VDD/2 is applied to the bit line BL. When data of DRAM is charged, that is, when the voltage of the capacitor CA is VDD, the charges in the capacitor CA gradually move to the bit line BL and the voltage of the bit line BL becomes slightly greater than VDD/2. On the other hand, when the data of the capacitor CA is discharged, the charges of the bit line BL move to the capacitor CA, and the voltage of the bit line BL becomes slightly lower than VDD/2. The potential difference of the bit line generated in this way is detected by using a sense amplifier and amplified to determine whether the data is “0” or “1”.

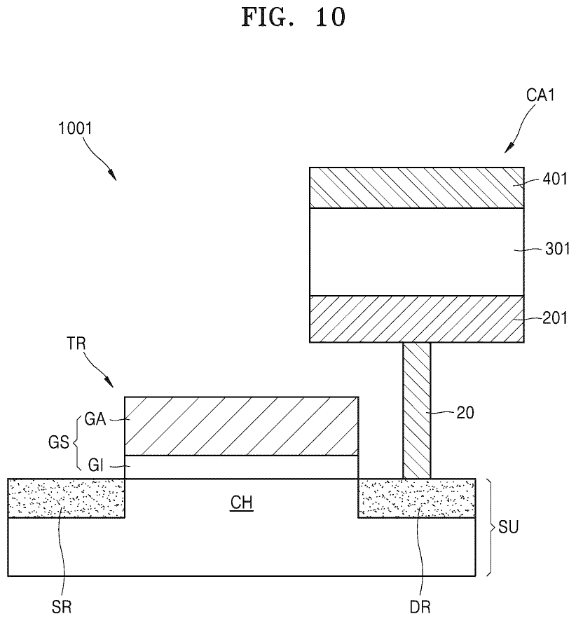

FIG. 10 is a schematic diagram illustrating an electronic device according to at least one embodiment.

Referring to FIG. 10, the electronic device 1001 may include a structure in which a capacitor CA1 and a transistor TR are electrically connected by a contact 20. The capacitor CA1 includes a lower electrode 201, an upper electrode 401 and a dielectric thin film 301 provided between the lower electrode 201 and the upper electrode 401. The capacitor CA1 may be the capacitor 100 as described in FIGS. 1 to 8. For example, the capacitor CA1 may include a lower electrode 201, which corresponds to the first thin film electrode layer 110 of FIGS. 1 and 2, a dielectric 301, which corresponds to the dielectric layer 150 and the interlayer 160 of FIGS. 1 and 2 (and/or the third interlayer 130 of FIG. 2), and an upper electrode 401, which corresponds to the second thin film electrode layer 190 of FIGS. 1 and 2, and a description thereof will be omitted.

The transistor TR may be a field effect transistor. The transistor TR may include: a semiconductor substrate SU having a source region SR, a drain region DR, and a channel region CH; and a gate stack GS disposed on a semiconductor substrate SU and facing the channel region CH, and having a gate insulating layer GI and a gate electrode GA.

The channel region CH is a region between the source region SR and the drain region DR, and is electrically connected to the source region SR and the drain region DR. The source region SR may be electrically connected to or in contact with one end of the channel region CH, and the drain region DR may be electrically connected to or in contact with the other end of the channel region CH. The channel region CH may be defined as a substrate region between source region SR and drain region DR in the semiconductor substrate SU.

The semiconductor substrate SU may include a semiconductor material. The semiconductor substrate SU may include, for example, an elemental and/or compound semiconductor material, such as silicon (Si), germanium (Ge), silicon germanium (SiGe), silicon carbide (SiC), gallium arsenide (GaAs), indium arsenide (InAs), indium phosphide (InP), etc. In at least one embodiment, the semiconductor substrate SU may include a silicon on insulator (SOI) substrate.

The source region SR, the drain region DR, and the channel region CH may be independently formed by injecting impurities into different regions of the semiconductor substrate SU, and in this case, the source region SR, the channel region CH, and the drain region DR may include a substrate material as a base material. The source region SR and the drain region DR may each include a conductive material. In this case, the source region SR and the drain region DR may include, for example, a metal, a metal compound, or a conductive polymer.

In at least some embodiments, the channel region CH may be implemented as a separate material layer (thin film). In these case, the channel region CH may include, for example, at least one selected from Si, Ge, SiGe, a Group III-V semiconductor, oxide semiconductor, nitride semiconductor, oxynitride semiconductor, two-dimensional material (2D material), quantum dots, and organic semiconductors. For example, the oxide semiconductor may include InGaZnO, etc., the 2D material may include transition metal dichalcogenide (TMD), graphene, and/or the like, and the quantum dots may include colloidal QDs a nanocrystal structure, and/or the like.

The gate electrode GA may be disposed above the semiconductor substrate SU while being spaced apart therefrom and facing the channel region CH. The gate electrode GA may include at least one selected from metal, metal nitride, metal carbide, and polysilicon. For example, the metal may include at least one selected from aluminum (Al), tungsten (W), molybdenum (Mo), titanium (Ti), and tantalum (Ta), and the metal nitride film may include at least one selected from a titanium nitride film (TiN film) and a tantalum nitride film (TaN film). The metal carbide may include at least one metal carbide that is doped with (or contains) aluminum and silicon. Examples thereof are TiAlC, TaAlC, TiSiC, or TaSiC.

The gate electrode GA may have a structure in which a plurality of materials are stacked. For example, the gate electrode GA may have a metal nitride layer/metal layer stacked structure such as TiN/Al or a metal nitride layer/metal carbide layer/metal layer stacked structure, such as TiN/TiAlC/W. However, these materials described above are only an example.

A gate insulating layer GI may be further disposed between the semiconductor substrate SU and the gate electrode GA. The gate insulating layer GI may include a paraelectric material or a high-k dielectric material, and may have a dielectric constant of about 20 to about 70.

The gate insulating layer GI may include silicon oxide, silicon nitride, aluminum oxide, hafnium oxide, zirconium oxide, or the like, or may include a 2D insulator such as hexagonal boron nitride (h-BN). For example, the gate insulating layer GI may include silicon oxide (SiO₂), silicon nitride (SiNₓ), and the like, and may include hafnium oxide (HfO₂), hafnium silicon oxide (HfSiO₄), lanthanum oxide (La₂O₃), and lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), red scandium tantalum oxide (PbSc_{0.5}Ta_{0.5}O₃), red zinc niobate (PbZnNbO₃), and/or the like. In addition, the gate insulating layer GI may include: a metal nitride oxide such as aluminum oxynitride (AlON), zirconiumoxy nitride (ZrON), hafniumoxy nitride (HfON), lanthanumoxy nitride (LaON), or yttriumoxynitride (YON); a silicate such as ZrSiON, HfSiON, YSiON, or LaSiON; an aluminate such as ZrAlON and HfAlON; and/or the like. In addition, the gate insulating layer GI may include the dielectric layers. The gate insulating layer GI may constitute a gate stack together with the gate electrode GA.

One of the electrodes 201 and 401 of the capacitor CA1 may be electrically connected to one of the source region SR and the drain region DR of the transistor TR, and may be electrically connected by, e.g., the contact 20. In this regard, the contact 20 may include an appropriate conductive material such as tungsten, copper, aluminum, polysilicon, and/or the like.

The arrangement of the capacitor CA1 and the transistor TR may be variously modified. For example, the capacitor CA1 may be disposed on the semiconductor substrate SU or may be embedded in the semiconductor substrate SU.

FIG. 10 shows an electronic device 1001 including one capacitor CA1 and one transistor TR. However, the illustrated example is only an example thereof. In some embodiments, the electronic device 1001 may include a plurality of capacitors and a plurality of transistors.

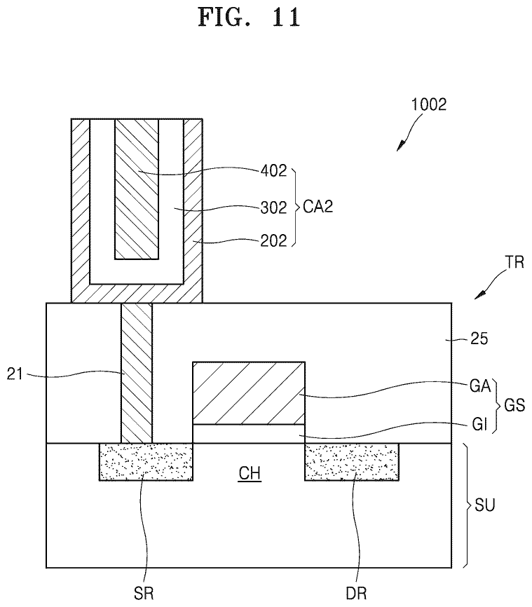

FIG. 11 is a schematic diagram illustrating an electronic device 1002 according to at least one embodiment.

Referring to FIG. 11, the electronic device 1002 may include a structure in which a capacitor CA2 and a transistor TR are electrically connected to each other by a contact 21.

The transistor TR may include: a semiconductor substrate SU having a source region SR, a drain region DR, and a channel region CH; and a gate stack GS disposed on a semiconductor substrate SU and facing the channel region CH, and having a gate insulating layer GI and a gate electrode GA.

An interlayer insulating film 25 may cover the gate stack GS on the semiconductor substrate SU. The interlayer insulating film 25 may include an insulating material. For example, the interlayer insulating film 25 may include Si oxide (for example, SiO₂), Al oxide (for example, Al₂O₃), or a high dielectric material (for example, HfO₂). The contact 21 penetrates the interlayer insulating film 25 and electrically connects the transistor TR and the capacitor CA1 to each other.

The capacitor CA1 includes a lower electrode 202, an upper electrode 402 and a dielectric thin film 302 provided between the lower electrode 202 and the upper electrode 402. The lower electrode 202 and the upper electrode 402 are presented in such a shape that can maximize the contact area with the dielectric thin film 302. For example, the lower electrode 202 may be presented in a cup shape and/or the upper electrode 402 may be in a pillar shape. The material for the capacitor CA2 may be substantially the same as that of the capacitor CA1 as described in FIG. 10 and/or capacitor 100 as described in FIGS. 1 to 8.

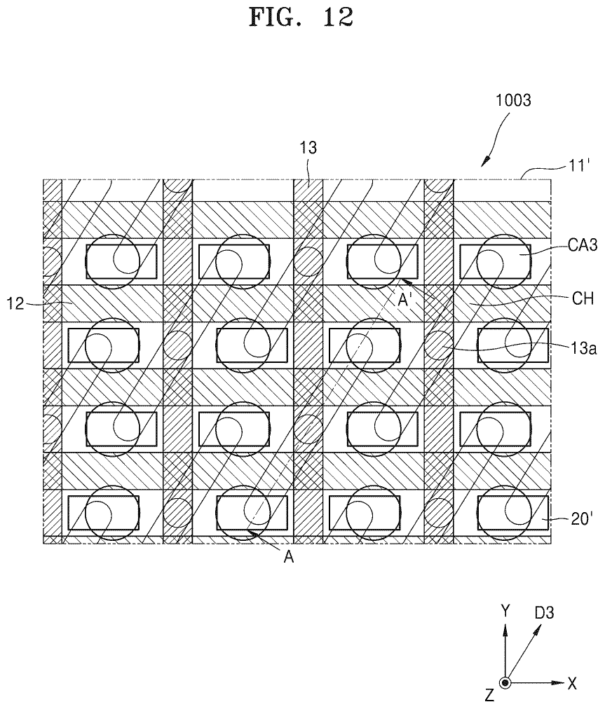

FIG. 12 is a plan view illustrating an electronic device according to at least one embodiment.

Referring to FIG. 12, an electronic device 1003 may include a plurality of capacitors and a plurality of field effect transistors which are repeatedly arranged. The electronic device 1003 may include: an electric field effect transistor including a semiconductor substrate 11′ including a source, a drain, and a channel, and a gate stack 12; a contact structure 20′ that does not overlap the gate stack 12 and is disposed on the semiconductor substrate 11′; and a capacitor CA3 disposed on the contact structure 20′, and the electronic device 1003 may further include a bit line structure 13 connecting a plurality of electric field effect transistors to each other.

Although FIG. 12 exemplarily illustrates the contact structure 20′ and the capacitor CA3 which are repeatedly arranged along X and Y directions, the arrangement is not limited thereto. For example, the contact structure 20′ may be arranged along the X and Y directions, and the capacitor CA3 may be arranged in a hexagonal shape such as a honeycomb structure.

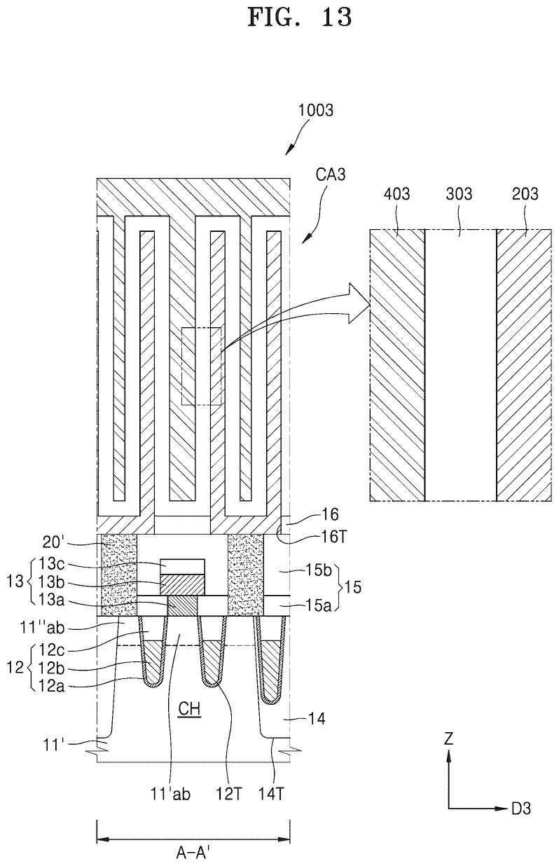

FIG. 13 is a cross-sectional view taken along line A-A′ of FIG. 12.

Referring to FIG. 13, the semiconductor substrate 11′ may have a shallow trench isolation (STI) structure including a device isolation film 14. The device isolation film 14 may be a single layer including one kind of insulating film or a multi-layer including a combination of two or more kinds of insulating films. The device isolation film 14 may 14 may include a device isolation trench 14T in the semiconductor substrate 11′ and the device isolation trench 14T may be filled with an insulating material. The insulating material may include at least one selected from fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and/or tonen silazene (TOSZ), but the materials therefor are not limited thereto.

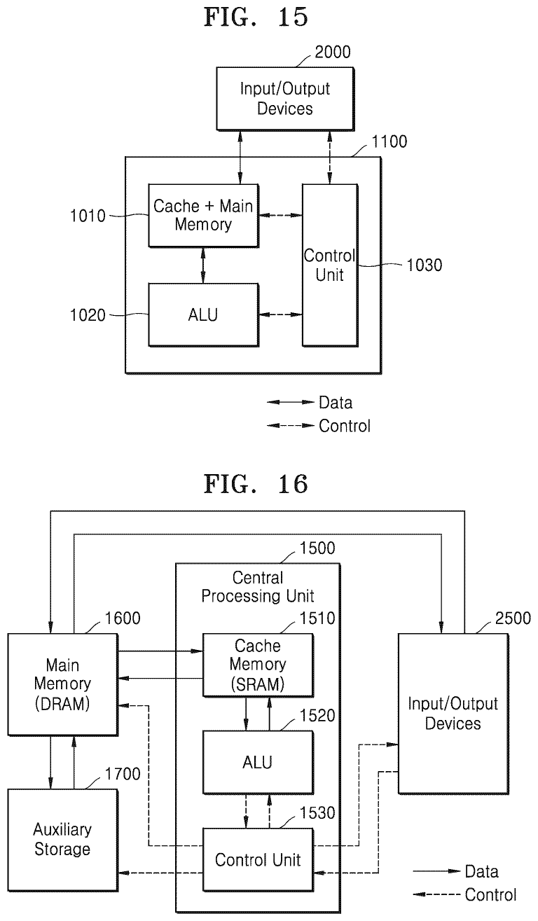

The semiconductor substrate 11′ may further include a channel region CH defined by the device isolation film 14 and a gate line trench 12T disposed parallel to an upper surface of the semiconductor substrate 11′ and extending in the X direction. The channel region CH may have a relatively long island shape having shorter and longer axes. A longer axis of the channel region CH may be arranged in a direction D3 parallel to the upper surface of the semiconductor substrate 11′ as shown in FIG. 15.

The gate line trench 12T may be disposed in the channel region CH or to cross the channel region CH at a predetermined depth from the upper surface of the semiconductor substrate 11′. The gate line trench 12T may also be disposed inside the device isolation trench 14T, and the gate line trench 12T inside the device isolation trench 14T may have a lower bottom surface than the gate line trench 12T of the channel region CH. The first source/drain 11′ab and the second source/drain 11″ab may be disposed on an upper portion of the channel region CH located on both sides of the gate line trench 12T.

A gate stack 12 may be disposed inside the gate line trench 12T. Specifically, a gate insulating layer 12a, a gate electrode 12b, and a gate capping layer 12c may be sequentially disposed inside the gate line trench 12T. The gate insulating layer 12a and the gate electrode 12b may be the same as described above, and the gate capping layer 12c may include at least one selected from silicon oxide, silicon oxynitride, and silicon nitride. The gate capping layer 12c may be disposed on the gate electrode GA to fill the remaining portion of the gate line trench 12T.

A bit line structure 13 may be disposed on the first source/drain 11′ab. The bit line structure 13 may be parallel to the upper surface of the semiconductor substrate 11′ and extend along the Y direction. The bit line structure 13 may be electrically connected to the first source/drain 11′ab and may sequentially include, on the substrate, a bit line contact 13a, a bit line 13b, and a bit line capping layer 13c. For example, the bit line contact 13a may include polysilicon, the bit line 13b may include a metal material, and the bit line capping layer 13c may include an insulating material such as silicon nitride or silicon oxynitride.

Referring to FIG. 13, the bit line contact 13a has a bottom surface at the same level as the upper surface of the semiconductor substrate 11′. However, this embodiment is just an example, and is not limited thereto. For example, in at least one embodiment, a recess formed to a certain depth from the upper surface of the semiconductor substrate 11″ is further provided, and the bit line contact 13a extends to the inside of the recess, so that the bottom surface of the bit line contact 13a is at a lower level than the upper surface of the semiconductor substrate 11′.

The bit line structure 13 may further include a bit line interlayer (not shown) between the bit line contact 13a and the bit line 13b. The bit line interlayer may include a metal silicide, such as tungsten silicide, or a metal nitride, such as tungsten nitride. In at least one embodiment, a bit line spacer (not shown) may be further formed on the sidewall of the bit line structure 13. The bit line spacer may have a single-layer structure or a multi-layer structure, and may include an insulating material such as silicon oxide, silicon oxynitride, or silicon nitride. In at least one embodiment, the bit line spacer may further include an air space (not shown).

The contact structure 20′ may be disposed on the second source/drain 11″ab. The contact structure 20′ and the bit line structure 13 may be disposed on different sources/drains on a substrate. The contact structure 20′ may have a structure in which a lower contact pattern (not shown), a metal silicide layer (not shown), and an upper contact pattern (not shown) are sequentially stacked on the second source/drain 11″ab. The contact structure 20′ may further include a barrier layer (not shown) surrounding the side surface and the bottom surface of the upper contact pattern. For example, the lower contact pattern may include polysilicon, the upper contact pattern may include a metal material, and the barrier layer may include a conductive metal nitride.

The capacitor CA3 may be electrically connected to the contact structure 20′ and disposed on the semiconductor substrate 11′. Specifically, the capacitor CA3 includes a lower electrode 203 electrically connected to the contact structure 20′, an upper electrode 403 spaced apart from the lower electrode 203, and a dielectric thin film 303 disposed between the lower electrode 203 and the upper electrode 403. The lower electrode 203 may have a cylindrical shape or a cup shape with an inner space that is closed at the bottom thereof. The upper electrode 403 may have a comb shape having comb teeth extending into the inner space formed by the lower electrode 203 and a region between adjacent lower electrodes 203. The dielectric thin film 303 may be disposed to be parallel to surfaces of the lower electrode 203 and the upper electrode 403 therebetween.

The materials constituting the capacitor CA3, are substantially the same as described in connection with the capacitor 100 described above in FIGS. 1 to 8. For example, the capacitor CA3 may include a lower electrode 203, which corresponds to the first thin film electrode layer 110 of FIGS. 1 and 2, a dielectric thin film 303, which corresponds to the dielectric layer 150 and the interlayer 160 of FIGS. 1 and 2 (and/or the third interlayer 130 of FIG. 2), and an upper electrode 403, which corresponds to the second thin film electrode layer 190 of FIGS. 1 and 2, therefor a description thereof will be omitted.

An interlayer insulating film 15 may be further disposed between the capacitor CA3 and the semiconductor substrate 11′. The interlayer insulating film 15 may be disposed in a space between the capacitor CA3 and the semiconductor substrate 11′ where no other structure is disposed. In detail, the interlayer insulating film 15 may be disposed to cover the interconnection and/or the electrode structure, for example, the bit line structure 13, the contact structure 20′, and the gate stack 12 on the substrate. For example, the interlayer insulating film 15 may surround the wall of the contact structure 20′. The interlayer insulating film 15 may include a first interlayer insulating film 15a surrounding the bit line contact 13a and a second interlayer insulating film 15b covering side surfaces and/or upper surfaces of the bit line 13b and the bit line capping layer 13c.

The lower electrode 203 of the capacitor CA3 may be disposed on the interlayer insulating film 15, for example, on the second interlayer insulating film 15b. Also, when a plurality of capacitors CA3 are disposed, bottom surfaces of the plurality of lower electrodes 203 may be separated by an etch stop layer 16. In other words, the etch stop layer 16 may 16 may have an opening 16T, and the bottom surface of the lower electrode 203 of the capacitor CA3 may be disposed in the opening 16T. The lower electrode 203 may have, as illustrated, a cylindrical shape or a cup shape with an inner space that is closed at the bottom thereof. The capacitor CA3 may further include a support portion (not shown) preventing the lower electrode 203 from tilting or falling, and the support portion may be disposed on a sidewall of the lower electrode 203.

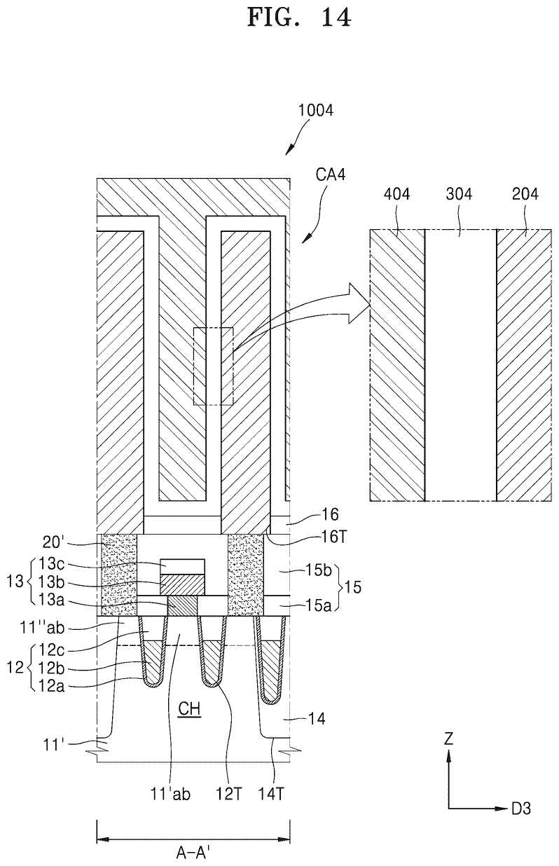

FIG. 14 is a cross-sectional view illustrating an electronic device 1004 according to at least one embodiment.

The electronic device 1004 of the present example corresponds to a cross-sectional view taken along the A-A′ of FIG. 12, and is different from FIG. 13 only in the shape of a capacitor CA4. The capacitor CA4 is electrically connected to the contact structure 20′ and disposed on the semiconductor substrate 11′, and includes a lower electrode 204 electrically connected to the contact structure 20′, an upper electrode 404 spaced apart from the lower electrode 204, and a dielectric thin film 304 disposed between the lower electrode 204 and the upper electrode 404. The materials constituting the capacitor CA4, are substantially the same as described in connection with the capacitor 100 described above in FIGS. 1 to 8. For example, the capacitor CA4 may include a lower electrode 203, which corresponds to the first thin film electrode layer 110 of FIGS. 1 and 2, a dielectric thin film 303, which corresponds to the dielectric layer 150 and the interlayer 160 of FIGS. 1 and 2 (and/or the third interlayer 130 of FIG. 2), and an upper electrode 403, which corresponds to the second thin film electrode layer 190 of FIGS. 1 and 2, therefor a description thereof will be omitted.

The lower electrode 204 may have a pillar shape such as a cylinder, a quadrangular pillar, or a polygonal pillar, each extending in a vertical direction (Z direction). The upper electrode 404 may have a comb shape having comb teeth extending to an area between adjacent lower electrodes 204. The dielectric thin film 304 may be disposed to be parallel to the surfaces of the lower electrode 204 and the upper electrode 404 therebetween.

Capacitors and electronic devices according to the embodiments described above can be applied to various application fields. For example, an electronic device according to embodiments may be applied as a logic element or a memory element. Electronic devices according to embodiments may be used for arithmetic operations, program execution, temporary data retention, and the like in devices such as mobile devices, computers, notebooks, sensors, network devices, and neuromorphic devices. In addition, electronic elements and electronic devices according to the embodiments may be useful for a device in which a data transmission amount is large and data transmission is continuously performed.

FIGS. 15 and 16 are conceptual diagrams schematically illustrating an electronic device architecture 1100 that may be applied to devices according to embodiments.

Referring to FIG. 15, an electronic element architecture 1100 may include a memory unit 1010, an arithmetic logic unit (ALU) 1020, and a control unit 1030. The memory unit 1010, the ALU 1020 and the control unit 1030 may be electrically connected to each other. For example, the electronic element architecture 1100 may be implemented as a single chip including the memory unit 1010, the ALU 1020, and the control unit 1030.

The memory unit 1010, the ALU 1020, and the control unit 1030 may be connected to each other through a metal line on-chip and communicate together directly. The memory unit 1010, the ALU 1020, and the control unit 1030 may be monolithically integrated on one substrate to form one chip. An input/output device 2000 may be connected to the electronic element architecture 1100, which may be a chip. In at least one embodiment, the memory unit 1010 may include a main memory and a cache memory. The electronic element architecture 1100, which may be a chip, may be an on-chip memory processing unit. The memory unit 1010 may include a capacitor as described above, and an electronic device using the capacitor. The ALU 1020 or the control unit 1030 may each include the capacitor.

Referring to FIG. 15, a cache memory 1510, an ALU 1520, and a control unit 1530 may configure a central processing unit (CPU) 1500, and the cache memory 1510 may 1510 may include a static random access memory (SRAM). In addition to the CPU 1500, a main memory 1600 and an auxiliary storage 1700 may be provided. The main memory 1600 may 1600 may be a dynamic random access memory (DRAM) and may include the capacitor described above. In some cases, an electronic element architecture may be implemented in such a form that computing unit elements and memory unit elements are adjacent to each other in one chip without distinction of sub-units.

The disclosure will be described in more detail through the following Examples and Comparative Examples. However, Examples are intended to illustrate the present disclosure, and the scope of the present disclosure is not limited thereto.

### EXAMPLES

### Manufacture of Capacitors

### Example 1: TiN/MoO₂/SnO₂(4.5 Å)/Al-Doped TiO₂(48 Å)/SnO₂(0.6 Å)/Al₂O₃ (1 Å)/Pt (500 Å), Addition of Al₂O₃ Twice at ATO

A TiN thin film was grown on a substrate using atomic layer deposition (ALD), and a MoO₂ thin film was grown on the TiN thin film using pulsed laser deposition (PLD) to form a first thin film electrode (e.g., 110 of FIGS. 1 and 2). The MoO₂ thin film had a rutile crystal structure.

A SnO₂ thin film was grown on the first thin film electrode by using an ALD method to form a third interlayer (e.g., 130 of FIG. 2) having a thickness of 4.5 Å. The SnO₂ thin film had a rutile crystal structure.

An Al-doped TiO₂ (ATO) thin film was grown on the third interlayer by an ALD method to form a dielectric layer (e.g., 150 of FIGS. 1 and 2) having a thickness of 48 Å. Al₂O₃ was added 2 times during a growth of TiO2 thin film to form Al-doped TiO2 thin film. The Al-doped TiO₂ thin film had a rutile-phase crystal structure.

A SnO₂ thin film was grown on the dielectric layer by an ALD method to form a second interlayer having a thickness of 0.6 Å, and an Al₂O₃ thin film was grown on the second interlayer by an ALD method to form a first interlayer having a thickness of 1 Å.

A Pt thin film was grown on the first interlayer by an evaporator method to form a second thin film electrode (e.g., 190 of FIGS. 1 and 2) having a thickness of 500 Å.

### Example 2: TiN/MoO₂/SnO₂(4.5 Å)/Al-Doped TiO₂(48 Å)/SnO₂(1 Å)/Al₂O₃ (1 Å)/Pt (500 Å), Addition of Al₂O₃ Twice at ATO

A capacitor was manufactured in the same manner as in Example 1, except that the thickness of the second interlayer was changed to be 1 Å in the manufacturing method of Example 1.

### Example 3: TiN/MoO₂/SnO₂(4.5 Å)/Al-doped TiO₂(48 Å)/SnO₂(0.3 Å)/Al₂O₃ (1 Å)/Pt (500 Å), addition of Al₂O₃ Twice at ATO

A capacitor was manufactured in the same manner as in Example 1, except that the thickness of the second interlayer was changed to be 0.3 Å in the manufacturing method of Example 1.

### Example 4: TiN/MoO₂/SnO₂(4.5 Å)/Al-Doped TiO₂(48 Å)/SnO₂(0.6 Å)/Al₂O₃ (1 Å)/Pt (500 Å), Addition of Al₂O₃ 2.5 Times at ATO

A capacitor was manufactured in the same manner as in Example 1, except that Al₂O₃ was added 2.5 times in the manufacturing method of Example 1.

### Example 5: TiN/MoO₂/SnO₂(4.5 Å)/Al-Doped TiO₂(48 Å)/SnO₂(0.3 Å)/Al₂O₃ (1 Å)/Pt (500 Å), Addition of Al₂O₃ 2.5 Times at ATO

A capacitor was manufactured in the same manner as in Example 3, except that Al₂O₃ was added 2.5 times in the manufacturing method of Example 3.

### Comparative Example 1: TiN/MoO₂/SnO₂(4.5 Å)/Al-Doped TiO₂ (48 Å)/Pt (500 Å), Al₂O₃ was Added Twice at ATO

A capacitor was manufactured in the same manner as in Example 1, except that the formation of the second interlayer and the first interlayer was omitted and a Pt thin film was grown on the dielectric layer by an evaporator method to form a second thin film electrode having a thickness of 500 Å, in the manufacturing method of Example 1.

### Comparative Example 1: TiN/MoO₂/SnO₂(4.5 Å)/Al-Doped TiO₂ (48 Å)/Pt (500 Å), Al₂O₃ was Added Twice at ATO

A capacitor was manufactured in the same manner as in Example 2, except that the formation of the first interlayer was omitted, and a Pt thin film was grown on the second interlayer by an evaporator method to form a second thin film electrode having a thickness of 500 Å, in the manufacturing method of Example 2.

### Comparative Example 3: TiN/MoO₂/SnO₂(4.5 Å)/Al-Doped TiO₂(48 Å)/SnO₂ (2 Å)/Pt (500 Å), Addition of Al₂O₃ Twice at ATO

A capacitor was manufactured in the same manner as in Comparative Example 2, except that the thickness of the second interlayer was changed to be 2 Å in the manufacturing method of Comparative Example 2.

### Comparative Example 4: TiN/MoO₂/SnO₂(4.5 Å)/Al-Doped TiO₂(48 Å)/Al₂O₃ (1 Å)/Pt (500 Å), Addition of Al₂O₃ Twice at ATO

A capacitor was manufactured in the same manner as in Example 1, except that the formation of the second interlayer was omitted, an Al₂O₃ thin film was grown on the dielectric layer by an ALD method to form a first interlayer having a thickness of 1 Å, and a

Pt thin film was grown on the first interlayer using an evaporator method to form a second thin film electrode having a thickness of 500 Å.

### Comparative Example 5: TiN/MoO₂/SnO₂(4.5 Å)/Al-Doped TiO₂(48 Å)/Al₂O₃ (2 Å)/Pt (500 Å), Addition of Al₂O₃ Twice at ATO

A capacitor was manufactured in the same manner as in Comparative Example 4, except that the thickness of the first interlayer was changed to be 2 Å in the manufacturing method of Comparative Example 4.

Comparative Example 6: TiN/MoO₂/SnO₂(4.5 Å)/Al-Doped TiO₂(48 Å)/Al₂O₃ (1 Å)/Pt (500 Å), Addition of Al₂O₃ 2.5 Times at ATO

A capacitor was manufactured in the same manner as in Comparative Example 4, except that Al₂O₃ was added 2.5 times in the manufacturing method of Comparative Example 4.

### Evaluation Example 1: TEM Analysis

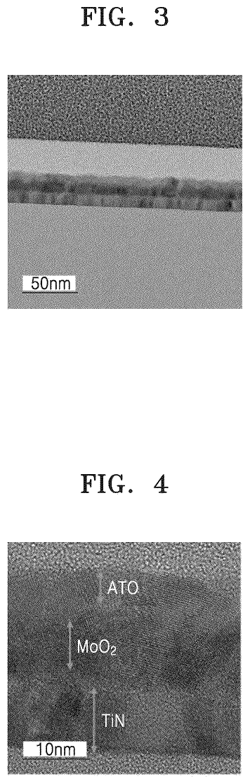

The HR-TEM and energy dispersive X-ray spectroscopy (EDS) mapping images of the cross section of the first thin film electrode layer/third interlayer/dielectric layer/second interlayer/first interlayer stack before the second thin film electrode layer was disposed in Example 1, were measured, and results thereof are shown in FIGS. 3, 4, and 5A to 5F.

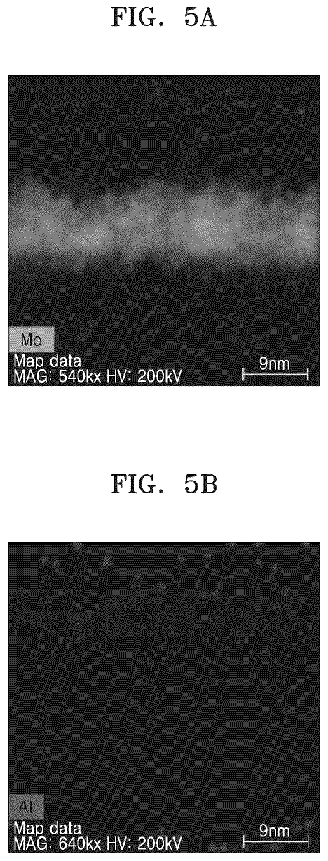

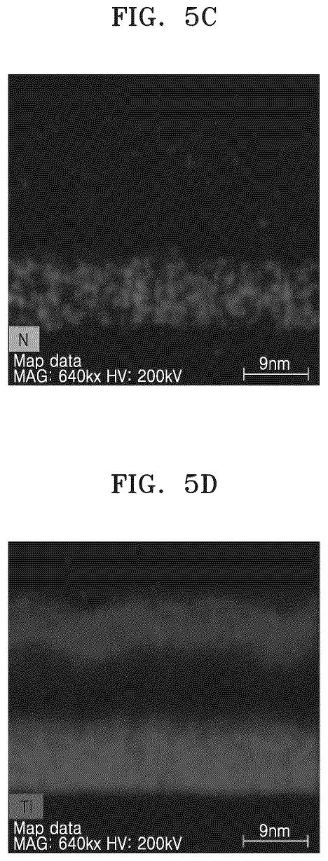

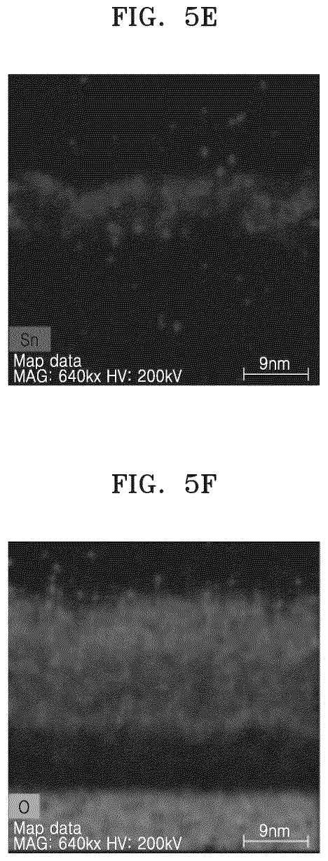

FIGS. 3 and 4 show a high-resolution transmission electron microscopy (HR-TEM) image of a cross-section of the first thin film electrode layer/third interlayer/dielectric layer/second interlayer/first interlayer stack manufactured in Example 1. FIGS. 5A to 5F show EDS elemental mapping images for the stack of FIG. 3.

Referring to FIGS. 3 and 4, it can be confirmed that the rutile shape was well maintained and referring to FIGS. 5A to 5F it can be confirmed that the stack structure was well grown without intermixing of respective layers.

### Evaluation Example 2: characteristics of leakage current

The leakage current of the capacitors manufactured in Examples 1 and 2 and

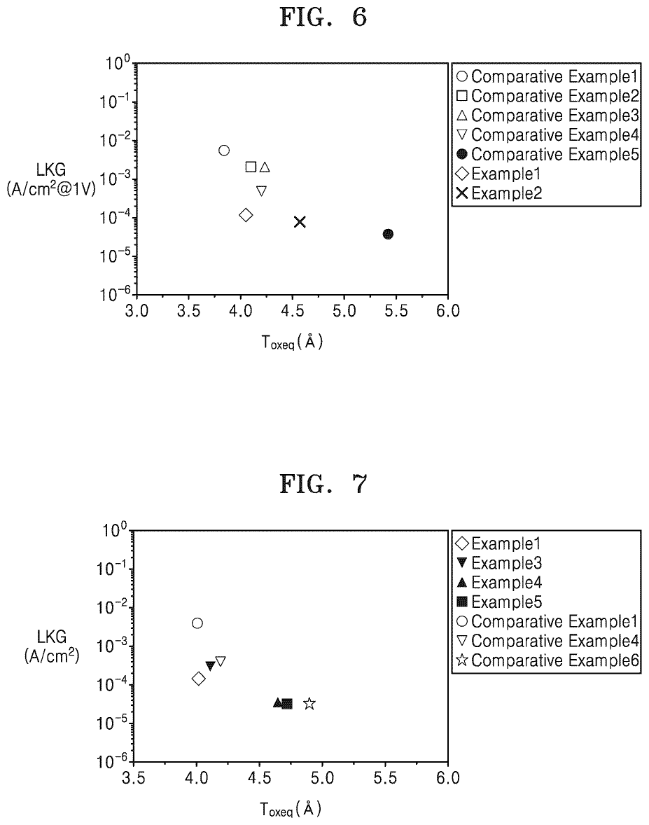

Comparative Examples 1 to 5 according to effective oxide film thickness (T_{oxeq}) was measured. Results thereof are shown in FIG. 6.

Referring to FIG. 6, it can be confirmed that Examples 1 and 2 exhibit relatively small effective oxide film thickness, that is, high permittivity and low leakage current characteristics, compared to Comparative Examples 1 to 5.

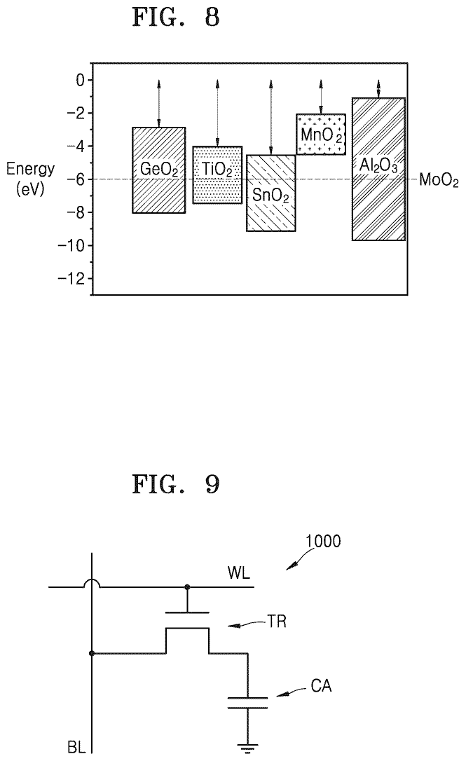

The leakage current of the capacitors manufactured in Examples 1, 3, 4 and 5 and Comparative Examples 1, 2, and 6 according to effective oxide film thickness (T_{oxeq}) was measured. Results thereof are shown in FIG. 7.

Referring to FIG. 7, it can be seen that compared to Comparative Examples 1 and 2, Examples 1 and 3 show relatively small effective oxide film thickness, that is, high permittivity and low leakage current characteristics, and Examples 4 and 5 have relatively high permittivity compared to Comparative Example 6.

### Evaluation Example 3: Electron affinity and Chemical potential properties

Referring to FIG. 8, which shows a graph showing the electron affinity of metal oxides, it can be seen that, in Example 1 to 5, the electron affinity of SnO₂ used as a second metal oxide, which is an example of the second interlayer material, was higher than the electron affinity of TiO₂ used as a third metal oxide, which is an example of a dielectric layer material. Further, although not disclosed in Figures, chemical potential of SnO₂ used as a second metal oxide, which is a second interlayer material, was also higher than the chemical potential of TiO₂ used as a third metal oxide, which is a dielectric layer material.

Hereinbefore, examples have been described. However, the examples are provided only for illustrative purpose, and various modifications thereof can be made by a person skilled in the art.

Capacitors described above and electronic devices including the same have been described with reference to embodiments illustrated in the drawings. However, it would be obvious to a person skilled in the art that various modifications and other equivalent embodiments can be made based on the embodiments presented herein. Therefore, the disclosed embodiments should be considered from an illustrative aspect rather than a limiting aspect. The scope of the present specification is shown in the claims rather than the foregoing description, and all differences within an equivalent scope should be construed as being included in the scope of rights.

A capacitor including an interlayer can have low leakage current and T_{oxeq}, and thus, electron transport characteristics thereof are excellent. Therefore, a high-quality device can be implemented using the capacitor.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first thin film electrode layer;
a second thin film electrode layer;
a dielectric layer between the first thin film electrode layer and the second thin film electrode layer; and
an interlayer between the second thin film electrode layer and the dielectric layer, the interlayer including a first metal oxide and a second metal oxide having a rutile phase,
wherein the dielectric layer includes a third metal oxide having a rutile phase,
the first metal oxide includes at least one of Al₂O₃ or MgO,
the second metal oxide includes at least one of SnO₂, GeO₂, or MnO₂,
the third metal oxide includes at least one of TiO₂, Ti₁₋ₓGaₓO₂ (0.01≤x≤0.1), Ti₁₋ₓAlₓO₂ (0.01≤x≤0.1), Ti₁₋ₓLaₓO₂ (0.01≤x≤0.1), Ti₁₋ₓBₓO₂ (0.01≤x≤0.1), Ti₁₋ₓInₓO₂ (0.01≤x≤0.1), Ti₁₋ₓScₓO₂ (0.01≤x≤0.1), or Ti₁₋ₓYₓO₂ (0.01≤x≤0.1), and
the first metal oxide, the second metal oxide, and the third metal oxide have different compositions from each other.

2. The capacitor of claim 1, wherein a ratio of a content of the second metal oxide to a content of the first metal oxide is at least about 10 at % and not more than about 90 at %.

3. The capacitor of claim 1, wherein
the interlayer includes a first interlayer and a second interlayer, the second interlayer between the first interlayer and the dielectric layer,
the first interlayer includes the first metal oxide, and
the second interlayer includes the second metal oxide.

4. The capacitor of claim 3, wherein a thickness of the second interlayer is less than 1 Å.

5. The capacitor of claim 1, further comprising:
a third interlayer between the first thin film electrode layer and the dielectric layer, the third interlayer including a fourth metal oxide having a rutile-phase crystal structure,
wherein the fourth metal oxide includes at least one of SnO₂, GeO₂, or MnO₂.

6. The capacitor of claim 1, wherein the first thin film electrode layer comprises:
a second lower electrode layer spaced apart from the dielectric layer, and
a first lower electrode layer between the second lower electrode layer and the dielectric layer, the first lower electrode layer including a fifth metal oxide having a rutile phase, and
wherein the fifth metal oxide includes at least one of MoO₂, VO₂, Mo₁₋ₓNbₓO₂ (0.01≤x≤0.1), Mo₁₋ₓTaₓO₂ (0.01≤x≤0.1), Mo₁₋ₓSbₓO₂ (0.01≤x≤0.1), Mo₁₋ₓMnₓO₂ (0.01≤x≤0.1), Mo₁₋ₓFeₓO₂ (0.01≤x≤0.1), V₁₋ₓNbₓO₂ (0.01≤x≤0.1), V₁₋ₓTaₓO₂ (0.01≤x≤0.1), V₁₋ₓSbₓO₂ (0.01≤x≤0.1), V₁₋ₓMnₓO₂ (0.01≤x≤0.1), or V₁₋ₓFeₓO₂ (0.01≤x≤0.1).

7. The capacitor of claim 1, wherein a chemical potential of the second metal oxide is greater than a chemical potential of the third metal oxide.

8. A capacitor comprising:
a first thin film electrode layer;
a second thin film electrode layer;
a dielectric layer between the first thin film electrode layer and the second thin film electrode layer; and
an interlayer between the second thin film electrode layer and the dielectric layer, the interlayer including a first metal oxide and a second metal oxide having a rutile phase,
wherein the dielectric layer includes a third metal oxide having a rutile phase,
the first metal oxide, the second metal oxide, and the third metal oxide have different compositions,
a band gap energy of the first metal oxide is 5.0 eV or more,
a chemical potential of the second metal oxide is greater than a chemical potential of the third metal oxide, and
the third metal oxide includes at least one of TiO₂, Ti₁₋ₓGaₓO₂ (0.01≤x≤0.1), Ti₁₋ₓAlₓO₂ (0.01≤x≤0.1), Ti₁₋ₓLaₓO₂ (0.01≤x≤0.1), Ti₁₋ₓBₓO₂ (0.01≤x≤0.1), Ti₁₋ₓInₓO₂ (0.01≤x≤0.1), Ti₁₋ₓScₓO₂ (0.01≤x≤0.1), or Ti₁₋ₓYₓO₂ (0.01≤x≤0.1).

9. The capacitor of claim 8, further comprising:
a third interlayer between the first thin film electrode layer and the dielectric layer,
wherein the first thin film electrode layer comprises:
a second lower electrode layer spaced apart from the dielectric layer, and
a first lower electrode layer between the second lower electrode layer and the dielectric layer,
wherein the third interlayer includes a fourth metal oxide having a rutile-phase crystal structure,
the first lower electrode layer includes a fifth metal oxide having a rutile phase, and
the third metal oxide, the fourth metal oxide, and the fifth metal oxide have different compositions from each other.

10. The capacitor of claim 8, wherein a ratio of a content of the second metal oxide to a content of the first metal oxide is at least about 1 at % and not more than about 90 at %.

11. The capacitor of claim 8, wherein
the interlayer includes a first interlayer and a second interlayer between the first interlayer and the dielectric layer,
the first interlayer includes the first metal oxide, and
the second interlayer includes the second metal oxide.

12. The capacitor of claim 11, wherein a thickness of the second interlayer is less than 1 Å.

13. The capacitor of claim 8, wherein the first metal oxide includes at least one of Al₂O₃ or MgO.

14. The capacitor of claim 9, wherein the second metal oxide and the fourth metal oxide each independently include at least one of SnO₂, GeO₂, or MnO₂.

15. The capacitor of claim 9, wherein the second metal oxide and the fourth metal oxide are different from each other.

16. The capacitor of claim 9, wherein the fifth metal oxide includes at least one of MoO₂, VO₂, Mo₁₋ₓNbₓO₂ (0.01≤x≤0.1), Mo₁₋ₓTaₓO₂ (0.01≤x≤0.1), Mo₁₋ₓSbₓO₂ (0.01≤x≤0.1), Mo₁₋ₓMnₓO₂ (0.01≤x≤0.1), Mo₁₋ₓFeₓO₂ (0.01≤x≤0.1), V₁₋ₓNbₓO₂ (0.01≤x≤0.1), V₁₋ₓTaₓO₂ (0.01≤x≤0.1), V₁₋ₓSbₓO₂ (0.01≤x≤0.1), V₁₋ₓMnₓO₂ (0.01≤x≤0.1), or V₁₋ₓFeₓO₂ (0.01≤x≤0.1).

17. An electronic device comprising:
a transistor; and
the capacitor of claim 1 electrically connected to the transistor.

18. The electronic device of claim 17, wherein the transistor comprises:
a semiconductor substrate including a source region, a drain region, and a channel region between the source region and the drain region; and
a gate stack on the semiconductor substrate and facing the channel region, the gate stack including a gate insulating layer and a gate electrode.

19. The electronic device of claim 17, wherein the transistor comprises:
a semiconductor substrate including a source region, a drain region, and a channel region between the source region and the drain region; and
a gate stack in a trench extending into a surface of the semiconductor substrate, the gate stack facing the channel region and including a gate insulating layer and a gate electrode.

20. The electronic device of claim 17, wherein
the capacitor and the transistor are included in a memory unit; and
the electronic device further comprises a control unit electrically connected to the memory unit, the control unit configured to the memory unit.
